(19) United States
(12) Patent Application Publication
(10) Pub. No.: US 2026/0173490 A1
(43) Pub. Date: Jun. 18, 2026

(54) MEMORY DEVICE AND MANUFACTURING METHOD FOR MANUFACTURING MEMORY DEVICE

(71) Applicant: Samsung Electronics Co., Ltd., Suwon-si (KR)

(72) Inventors: Woon Ih CHOI, Suwon-si (KR); Uihui KWON, Suwon-si (KR); Hyung Joon KIM, Suwon-si (KR); Bokyeom KIM, Suwon-si (KR)

(73) Assignee: Samsung Electronics Co., Ltd., Suwon-si (KR)

(21) Appl. No.: 19/294,407

(22) Filed: Aug. 8, 2025

(30) Foreign Application Priority Data
Dec. 12, 2024 (KR) 10-2024-0185121
Apr. 14, 2025 (KR) 10-2025-0048082

(51) Int. Cl. H10D 64/68; H10B 43/10; H10B 43/30; H10B 51/10; H10B 51/30; H10D 64/01

(52) U.S. Cl. CPC H10D 64/683; H10B 43/10; H10B 43/30; H10B 51/10; H10B 51/30; H10D 64/033; H10D 64/037; H10D 64/689; H10D 64/691; H10D 64/693

(57) ABSTRACT

A memory device including a substrate, a channel layer on the substrate, a gate electrode on the channel layer, a nitride layer between the channel layer and the gate electrode, the nitride layer containing silicon nitride having a dopant, a gate insulating layer between the gate electrode and the nitride layer, and a channel insulating layer between the channel layer and the nitride layer. The nitride layer includes a first region and a second region further from the gate electrode than the first region in a thickness direction of the nitride layer, the dopant includes boron (B), aluminum (Al), gallium (Ga), indium (In), thallium (Tl), germanium (Ge), tin (Sn), lead (Pb), phosphorus (P), arsenic (As), antimony (Sb), or bismuth (Bi), and a ratio C_{D1}/C_{D2} of dopant concentration C_{D1} of the first region and dopant concentration C_{D2} of the second region is in a range of 0.8 to 1.2.

### CROSS-REFERENCE TO RELATED APPLICATION

This application claims priority to Korean Patent Application Nos. 10-2024-0185121, filed on Dec. 12, 2024, and 10-2025-0048082, filed on Apr. 14, 2025, respectively, with the Korean Intellectual Property Office, and claims all benefits accruing therefrom under 35 U.S.C. § 119. The contents of the aforementioned applications are incorporated herein by reference in their entirety.

### BACKGROUND

The present disclosure relates to a memory device and a method for manufacturing the memory device.

Manufacturing technology for NAND flash memory devices is being developed in a direction of improving the integration degree, operating speed, and yield of memory devices. For high integration of memory devices, vertical NAND (VNAND) flash memory devices have been proposed.

### SUMMARY

The present disclosure provides a memory device having improved charge trap flash (CTF) characteristics of a charge trap layer, a wide memory window, and improved retention.

The technical problems of the present disclosure are not limited to the technical problems mentioned above, and other technical problems not mentioned will be clearly understood by those skilled in the art from the description below.

According to some example embodiments of the present disclosure, a memory device comprises a substrate; a channel layer on a surface of the substrate; a gate electrode on the channel layer; a nitride layer between the channel layer and the gate electrode, the nitride layer containing silicon nitride having a dopant; a gate insulating layer between the gate electrode and the nitride layer; and a channel insulating layer between the channel layer and the nitride layer, wherein the nitride layer includes a first region adjacent to the gate electrode in a thickness direction of the nitride layer and a second region further from the gate electrode than the first region in the thickness direction of the nitride layer, the dopant includes one or more of boron (B), aluminum (Al), gallium (Ga), indium (In), thallium (Tl), germanium (Ge), tin (Sn), lead (Pb), phosphorus (P), arsenic (As), antimony (Sb), or bismuth (Bi), and a ratio C_{D1}/C_{D2} of a dopant concentration C_{D1} of the first region and a dopant concentration C_{D2} of the second region is in a range of 0.8 to 1.2.

According to some example embodiments of the present disclosure, a memory device comprises a substrate; a channel layer on a surface of the substrate; a gate electrode on the channel layer; a nitride layer between the channel layer and the gate electrode, the nitride layer containing silicon nitride having a dopant; a gate insulating layer between the gate electrode and the nitride layer; and a channel insulating layer between the channel layer and the nitride layer, wherein the nitride layer includes a first region adjacent to the gate electrode in a thickness direction of the nitride layer, a second region further from the gate electrode than the first region in the thickness direction of the nitride layer, and a third region between the first region and the second region, the dopant includes one or more of boron (B), aluminum (Al), gallium (Ga), indium (In), thallium (Tl), germanium (Ge), tin (Sn), lead (Pb), phosphorus (P), arsenic (As), antimony (Sb), or bismuth (Bi), and a dopant concentration C_{D2} of the second region is equal to or greater than each of a dopant concentration C_{D1} of the first region and a dopant concentration C_{D3} of the third region.

According to some example embodiments of the present disclosure, a memory device comprises a substrate; a channel layer on a surface of the substrate; a gate electrode on the channel layer; a nitride layer between the channel layer and the gate electrode, the nitride layer containing silicon nitride having a dopant; a gate insulating layer between the gate electrode and the nitride layer; and a channel insulating layer between the channel layer and the nitride layer, wherein the nitride layer includes a first region adjacent to the gate electrode in a thickness direction of the nitride layer, a second region further from the gate electrode than the first region in the thickness direction of the nitride layer, and a third region between the first region and the second region, the dopant includes one or more of boron (B), aluminum (Al), gallium (Ga), indium (In), thallium (Tl), germanium (Ge), tin (Sn), lead (Pb), phosphorus (P), arsenic (As), antimony (Sb), or bismuth (Bi), and a ratio C_{D1}/C_{D2} of a dopant concentration C_{D1} of the first region and a dopant concentration C_{D2} of the second region in a range of 0.8 to 1.2, a ratio C_{D3}/C_{D1} of a dopant concentration C_{D3} of the third region and the dopant concentration C_{D1} of the first region is in a range of 0.8 to 1.2, a ratio C_{D3}/C_{D2} of the dopant concentration C_{D3} of the third region and the dopant concentration C_{D2} of the second region is in a range of 0.8 to 1.2, the nitride layer contains doped germanium in an amount of 25 at % or less relative to a total element content of the nitride layer, a mole number of nitrogen contained in the nitride layer is greater than a mole number of silicon, and a thickness of the nitride layer is in a range of 1 nm to 10 nm.

According to some example embodiments of the present disclosure, a method for manufacturing a memory device comprises forming a mold structure in which a gap insulating layer and a sacrificial layer are alternately stacked in a first direction intersecting with a second direction, the second direction parallel to a surface of a substrate on the substrate, forming a hole penetrating the mold structure in the first direction, forming a gate insulating layer to overlap with a sacrificial layer in the first direction parallel to the surface of the substrate within the hole, forming a nitride layer containing a nitride doped having a dopant on the gate insulating layer by an atomic layer deposition (ALD) process, forming a channel insulating layer on the nitride layer, forming a channel layer to extend along the first direction within the hole; and removing the sacrificial layer and forming a gate electrode on at least a portion of the sacrificial layer removed, the dopant includes one or more of boron (B), aluminum (Al), gallium (Ga), indium (In), thallium (Tl), germanium (Ge), tin (Sn), lead (Pb), phosphorus (P), arsenic (As), antimony (Sb), or bismuth (Bi).

In the method for manufacturing the memory device, the atomic layer deposition process may comprise a first deposition process performed by injecting a silicon (Si) precursor and a second deposition process performed by injecting a dopant precursor.

In the method for manufacturing the memory device, the atomic layer deposition process may be performed so that the first deposition process and the second deposition process overlap at least in part.

In the method for manufacturing the memory device, in the atomic layer deposition process, the second deposition process may be performed discontinuously while the first deposition process is continuously performed.

In the method for manufacturing the memory device, in the atomic layer deposition process, after performing the first deposition process, the first deposition process may be performed discontinuously while the second deposition process is continuously performed.

In the method for manufacturing the memory device, the atomic layer deposition process may be performed by further injecting a nitrogen precursor.

Specific details of other embodiments are included in the detailed description and drawings.

### BRIEF DESCRIPTION OF THE DRAWINGS

The drawings illustrated in the present disclosure are according to embodiments, and the ratio of the width, depth, or height (or thickness) of each component is for describing the present disclosure in detail, and the ratio thereof may be different from the actual one. In addition, each component illustrated in the drawings may be illustrated exaggeratedly for describing the present disclosure in detail. In addition, in the coordinate system illustrated in the drawing, each axis may be perpendicular to each other, the direction pointed by the arrow may be the +direction, and the direction opposite to the direction pointed by the arrow (the direction rotated by 180 degrees) may be the-direction.

Some example embodiments can be understood in more detail from the following description taken in conjunction with the accompanying drawings, in which:

FIG. 1 is a simplified view of at least a portion of a memory device according to an embodiment of the present disclosure;

FIG. 2 illustrates a cross-section cut along AA′ of FIG. 1;

FIG. 3 illustrates a cross-section cut along BB′ of FIG. 1;

FIG. 4 is an enlarged view of portion P of FIG. 1;

FIG. 5 illustrates a simplified view of at least a portion of a memory device according to some example embodiments of the present disclosure;

FIG. 6 illustrates a cross-section cut along CC′ of FIG. 5;

FIG. 7 is an enlarged view of portion Q of FIG. 5;

FIG. 8 is a simplified view of at least a portion of a memory device according to some example embodiments of the present disclosure;

FIGS. 9 to 16 are diagrams for describing a method for manufacturing the memory device according to some example embodiments of the present disclosure;

FIG. 17 is a graph showing the relative energy (eV) after each germanium (Ge) element is substituted for the position of silicon in the existing amorphous silicon nitride and the structure is optimized. ;

FIG. 18 is a graph showing the frequency of occurrence by size of the Si—Si bonding network in a log scale;

FIG. 19 is a graph showing the number of coordination defects in a nitride layer according to the coordination of the germanium element for the nitride layer doped with germanium at approximately 1.8 at % of the total elements;

FIG. 20 is a graph showing the amount of change in electric charge of each element when electrons and holes are trapped; and

FIG. 21 is a graph showing a change in Löwdin charge (i.e., charge trap participation rate, %) for each dopant when electrons and holes are trapped in the nitride layer doped with approximately 1.8 at % of the total elements.

### DETAILED DESCRIPTION

Prior to the detailed description of the present disclosure, terms or words used in the specification and claims may not be construed as limited to their ordinary or dictionary meanings. In addition, the terms or words should be interpreted to have meanings and concepts consistent with the technical idea of the present disclosure, based on the principle that the inventor may appropriately define the concept of the terms in order to best explain his or her inventive concepts. The embodiments described in this specification and configurations illustrated in the drawings are merely the most preferred embodiments of the present disclosure and may not represent all of the technical ideas of the present disclosure. Accordingly, there may be various equivalents and modifications that can replace the embodiments and configurations at the time of filing of the present disclosure.

The same reference numbers or symbols described in each drawing attached to this specification may indicate parts or components that perform substantially the same function. For the convenience of explanation and understanding, the same reference numbers or symbols may be used in different embodiments. That is, even if components having the same reference number are illustrated in a plurality of drawings, the plurality of drawings may not all represent one embodiment.

When a component is described as being “on” or “in contact with” another component in this specification, it can be understood that a component may be in direct contact with or connected to another component, but there may be another component between them.

When a component is described as being “above” another component in this specification, it can be understood that the component is vertically above the other component, and that they may be in direct contact or connected, but that another component may be present between them. In addition, when a component is described as being “under” another component in this specification, it can be understood that they are vertically below each other, and that they may be in direct contact or connected, but that another component is present between them.

In the following description, singular expressions include plural expressions unless the context clearly indicates otherwise. Terms such as “include” or “comprise” are intended to designate the presence of a feature, number, step, operation, component, part, or combination thereof described in the specification, but can be understood as not excluding in advance the possibility of the presence or addition of one or more other features, numbers, steps, operations, components, parts, or combinations thereof.

In the following description, expressions such as upper side, upper surface, lower side, lower surface, side surface, front side, and rear side are expressed based on the direction depicted in the drawings, and may be expressed differently if the direction of the corresponding object changes.

In this specification and claims, terms including ordinal numbers such as “first” and “second” may be used to distinguish between components. These ordinals are sometimes used to distinguish between identical or similar components, and the use of these ordinals should not be interpreted limitedly due to the use of these ordinal numbers. As an example, components combined with these ordinal numbers should not be interpreted as limiting the order of use or arrangement, etc., by the number. If necessary, respective ordinal numbers may be used interchangeably.

Unless specifically limited in this specification, the SI unit system may be applied as the unit of physical properties.

While the term “same” may be used in description of some example embodiments, it should be understood that some imprecisions may exist. Thus, when one element or property is referred to as being the same as another element or property, it should be understood that the element or property is the same as another element or property within a desired manufacturing or operational tolerance range (e.g., ±10%).

It will be understood that elements and/or properties thereof described herein as being “substantially” or “approximately” the same as one or more other elements and/or properties thereof encompasses elements and/or properties thereof that have a relative difference in magnitude with the one or more other elements and/or properties thereof that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about,” “substantially,” or “approximately” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

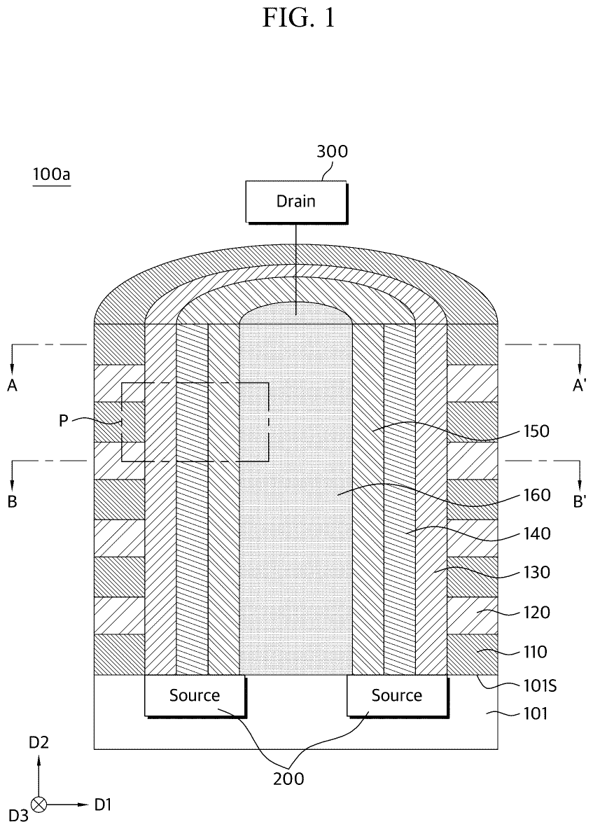

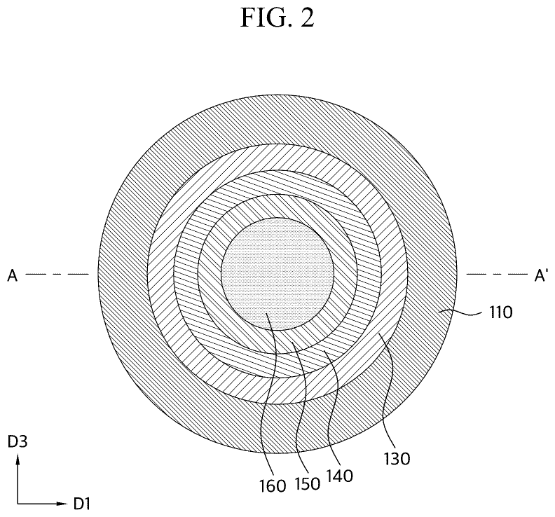

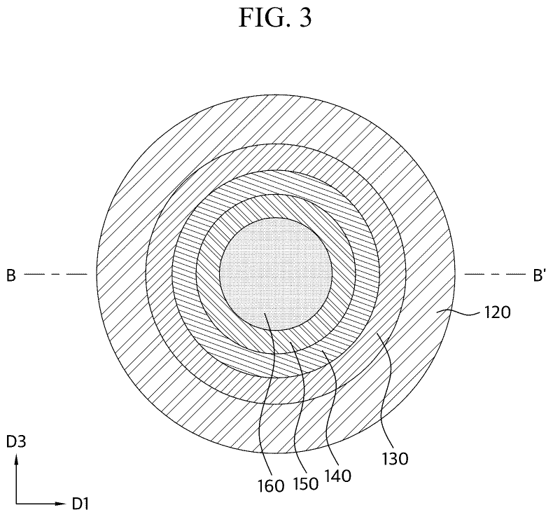

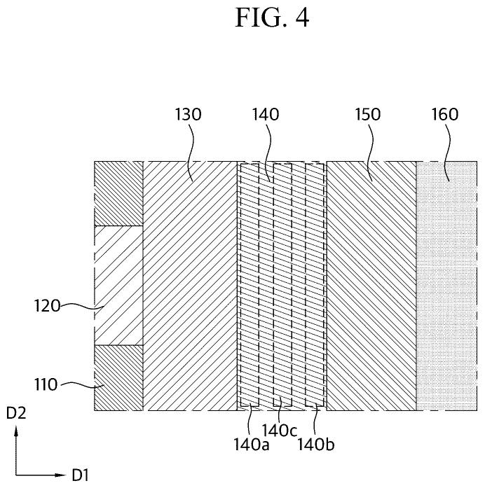

FIG. 1 is a simplified view of at least a portion of a memory device 100a according to some example embodiments of the present disclosure. FIG. 2 illustrates a cross-section cut along AA′ of FIG. 1. FIG. 3 illustrates a cross-section cut along BB′ of FIG. 1. FIG. 4 is an enlarged view of portion P of FIG. 1.

The memory device 100a according to some example embodiments of the present disclosure may be, for example, a non-volatile memory device. In one example, the non-volatile memory device may be, for example, a flash memory, a ROM, a hard disk, a diskette drive, a magnetic tape, or an optical disk, but is not limited thereto. In some example embodiments, the non-volatile memory device may be a flash memory. In one example, the flash memory may be a NAND flash memory, and specifically, may be a planar NAND flash memory or a vertical NAND flash memory. In one example, the memory device 100a may be the planar NAND flash memory or the vertical NAND flash memory device.

The memory device 100a according to some example embodiments of the present disclosure may include a substrate 101, a gate electrode 120, a gate insulating layer 130, a nitride layer 140, a channel insulating layer 150, and a channel layer 160.

The substrate 101 according to some example embodiments of the present disclosure may be, but is not particularly limited to, a silicon substrate, a plastic substrate, a glass substrate, a compound semiconductor substrate, a ceramic substrate, or a silicon on insulator (SOI) substrate. In some example embodiments, the substrate 101 may include, although not shown separately, an impurity region due to doping, a peripheral circuit that selects and controls an electronic device such as a transistor, or a memory cell. In some example embodiments, the gate electrode 120, the gate insulating layer 130, the nitride layer 140, the channel insulating layer 150, and the channel layer 160 may be disposed on a surface of the substrate.

In the present specification, a first direction D1 may be a direction parallel to a surface 101S of the substrate as illustrated in FIG. 1. A second direction D2 may mean a direction intersecting with the first direction D1, and specifically, the second direction D2 may be a direction perpendicular to the surface 101S of the substrate while intersecting with the first direction D1. A third direction D3 may be a direction intersecting with the first direction D1 as illustrated in FIG. 1, but is parallel to the surface 101S of the substrate. However, this is merely for exemplary purposes to facilitate understanding, and depending on the case, the direction parallel to the surface 101S of the substrate may correspond to the second direction, and the first direction may denote a direction intersecting the second direction. In addition, the first direction may be a direction perpendicular to the surface 101S of the substrate while intersecting with the first direction.

The gate electrode 120 according to some example embodiments of the present disclosure may be at least a part of a word line or may be electrically connected to a word line. In one example, the gate electrode 120 may contain a conductive material. In the present specification, the conductive material may have an electrical conductivity of 10⁶ S/m or more when measured at room temperature. In the present specification, electrical conductivity may be measured based on ASTM E 1004, but is not limited thereto. For example, the conductive material may contain one or more of metal, a metal alloy, a conductive metal nitride, a metal silicide, a doped semiconductor material, a conductive metal oxide, and a conductive metal oxynitride. For example, the conductive material may include, but is not limited to, one or more selected from a group consisting of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), and/or vanadium (V). The conductive metal oxide and conductive metal oxynitride may include, but are not limited to, oxidized forms of the materials described above.

The gate electrode 120 according to some example embodiments of the present disclosure may be disposed on the channel layer 160.

Referring to FIG. 1, in one example, the gate electrode 120 may surround at least a portion of the channel layer 160. In some example embodiments, the gate electrodes 120 may be plural, and adjacent gate electrodes 120 may be spaced apart from each other in the second direction D2.

The memory device 100a according to some example embodiments of the present disclosure may include a gap insulating layer 110.

Referring to FIG. 1, in one example, the gap insulating layer 110 may surround at least a portion of the channel layer 160. In one example, the gap insulating layer 110 may contain an insulating material. In this specification, the insulating material may have an electrical conductivity of approximately 10⁻⁶ S/m or less when the insulating material is measured at room temperature. For example, the insulating material may contain, but is not limited to, one or more compounds selected from a group consisting of silicon oxide, silicon nitride, silicon oxynitride, a low dielectric constant material, and a high dielectric constant material. In the present specification, the low dielectric constant material may have a permittivity of less than approximately 3.9 and may include, but is not limited to, for example, one or more from a group consisting of fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonn silazene (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, and mesoporous silica. In the present specification, the high dielectric constant material may have a permittivity of approximately 3.9 or higher and may include, but is not limited to, for example, one or more selected from a group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate.

The gap insulating layers 110 according to some example embodiments of the present disclosure may be plural, and adjacent gap insulating layers 110 may be spaced apart from each other in the second direction D2. In some example embodiments, the gap insulating layer 110 may be disposed to fill a space between the adjacent gate electrodes 120. In one example, the gap insulating layer 110 may overlap the gate electrode 120 in at least some regions of the gap insulating layer 110 when viewed from the second direction D2.

Referring to FIG. 1, in one example, the gap insulating layer 110 and the gate electrode 120 may have an alternately stacked structure, and the gap insulating layer 110 and the gate electrode 120 may be in contact with each other in the second direction D2. Referring to FIG. 2, the gap insulating layer 110 may surround at least a portion of the channel layer 160. Referring to FIG. 3, the gate electrode 120 may surround at least a portion of the channel layer 160. FIG. 4 is an enlarged view of portion P of FIG. 1.

The channel layer 160 according to some example embodiments of the present disclosure may be disposed on the surface 101S of the substrate.

Referring to FIG. 1, in one example, the channel layer 160 may be formed to extend along the second direction D2. In some example embodiments, the gate electrode 120 may surround at least a portion of the channel layer 160.

The channel layer 160 according to some example embodiments of the present disclosure may contain silicon (Si). For example, the channel layer 160 may include polysilicon. In another example, the channel layer 160 may contain a compound semiconductor. For example, the channel layer 160 may contain polysilicon. In another example, the channel layer 160 may contain, but is not limited to, one or more of indium oxide, tin oxide, zinc oxide, In—Zn(zinc) based oxide (IZO), Sn(tin)-Zn based oxide, Al(aluminum)-Zn based oxide, Zn—Mg(magnesium) based oxide, Sn—Mg based oxide, In—Mg based oxide, In—Ga based oxide (IGO), In—Ga—Zn based oxide (IGZO), In—Al—Zn based oxide, In—Sn—Zn based oxide, Sn—Ga—Zn based oxide, Al—Ga—Zn based oxide, Sn—Al—Zn based oxide, In—Hf(hafnium)-Zn based oxide, In—La(lanthanum)-Zn based oxide, In—Ce(cerium)-Zn based oxide, In—Pr(praseodymium)-Zn based oxide, In—Nd(neodymium)-Zn based oxide, In—Sm(samarium)-Zn based oxide, In—Eu(europium)-Zn based oxide, In—Gd(gadolinium)-Zn based oxide, In—Tb(terbium)-Zn based oxide, In—Dy(dystrosium)-Zn based oxide, In—Ho(holmium)-Zn based oxide, In—Er(erbium)-Zn based oxide, In—Tm(thulium)-Zn based oxide, In—Yb(ytterbium)-Zn based oxide, In—Lu(lutetium)-Zn based oxide, In—Sn—Ga—Zn based oxide, In—Hf—Ga—Zn based oxide, In—Al—Ga—Zn based oxide, In—Sn—Al—Zn based oxide, In—Sn—Hf—Zn based oxide, and/or In—Hf—Al—Zn based oxide.

The nitride layer 140 according to some example embodiments of the present disclosure may be disposed between the channel layer 160 and the gate electrode 120. In some example embodiments, the nitride layer 140 may contain silicon nitride having a dopant.

The dopant of the present disclosure may include one or more of boron (B), aluminum (Al), gallium (Ga), indium (In), thallium (Tl), germanium (Ge), tin (Sn), lead (Pb), phosphorus (P), arsenic (As), antimony (Sb), and/or bismuth (Bi). In some example embodiments, the dopant may include one or more of gallium (Ga), indium (In), germanium (Ge), tin (Sn), lead (Pb), phosphorus (P), arsenic (As), and/or antimony (Sb).

As the nitride layer 140 of the present disclosure contains silicon nitride doped with germanium (Ge), a larger silicon (Si)-silicon (Si) bonding network (i.e., a large number of long Si—Si bonds) is generated, and due to this, trapping of electrons and holes may occur more easily. In addition, the Si—Si bond is strengthened by substituting some silicon (Si) elements with the dopants, and through this, a deep trap can be generated. In the nitride layer 140, as a large amount of undercoordinated dopants are generated, reorganization of chemical bonds occurs, and the number of stably trapped electrons and holes may increase.

The nitride layer 140 of the present disclosure may have a dopant through doping. In some example embodiments, dopant doping may be performed by, for example, an atomic layer deposition (ALD) process. However, the present disclosure is not limited thereto.

Referring to FIG. 4, the nitride layer 140 according to some example embodiments of the present disclosure may include a first region adjacent to the gate electrode 120 in a thickness direction of the nitride layer 140 and a second region 140b located further from the gate electrode 120 than the first region 140a in the thickness direction of the nitride layer 140. Referring to FIG. 4, the thickness direction of the nitride layer 140 may mean the first direction D1 in some example embodiments. However, the example embodiments are not so limited thereto. For example, in some example embodiments, as depicted in FIGS. 2 and 3, a thickness direction of the nitride layer 140 may refer to a radially inward direction from a common axis around which the channel insulating layer 150, the nitride layer 140, and the gate insulating layer 130 are coaxially aligned.

In one example, a ratio C_{D1}/C_{D2} of dopant concentration C_{D1} of the first region 140a and doped germanium concentration C_{D2} of the second region 140b may be, for example, approximately 0.8 to approximately 1.2, approximately 0.85 to approximately 1.15, approximately 0.9 to approximately 1.1, approximately 0.95 to approximately 1.05, or approximately 1. In one example, the concentration (at %) of dopants may mean a ratio of the number of dopants present in a specific region to the number of all elements present in the specific region. In one example, the concentration of dopants may be measured by a method such as secondary ion mass spectrometry (SIMS), but is not limited thereto.

The nitride layer 140 according to some example embodiments of the present disclosure may be divided into two or more regions according to the distance from the gate electrode 120. The nitride layer 140 according to some example embodiments of the present disclosure may further include a third region 140c between the first region 140a and the second region 140b. A ratio C_{D3}/C_{D1} of the dopant concentration C_{D3} of the third region 140c and the dopant concentration C_{D1} of the first region may be approximately 0.8 to approximately 1.2, approximately 0.85 to approximately 1.15, approximately 0.9 to approximately 1.1, approximately 0.95 to approximately 1.05, or approximately 1. A ratio C_{D3}/C_{D2} of the dopant concentration C_{D3} of the third region and the dopant concentration C_{D2} of the second region may be, for example, approximately 0.8 to approximately 1.2, approximately 0.85 to approximately 1.15, approximately 0.9 to approximately 1.1, approximately 0.95 to approximately 1.05, or approximately 1.

The dopant concentration of the nitride layer 140 according to some example embodiments of the present disclosure may be uniform throughout the nitride layer 140. The nitride layer 140 having a uniform dopant concentration may be manufactured, for example, by depositing silicon nitride and simultaneously doping dopant through an atomic layer deposition (ALD) process. In the present specification, the meaning of the concentration being uniform may mean that the concentration is substantially uniform. This is shown by the fact that the ranges of the ratios (e.g., C_{D1}/C_{D2}, C_{D3}/C_{D1}, and C_{D3}/C_{D2}) between the dopant concentration (C_{D1}) of the first region 140a, the dopant concentration C_{D2} of the second region 140b, and the dopant concentration C_{D3} of the third region 140c are 0.8 to 1.2. In addition, the nitride layer 140 may not have a gradient where the dopant concentration increases as it approaches the gate electrode 120.

According to some example embodiments of the present disclosure, the nitride layer 140 may include the first region 140a, the second region 140b, and the third region 140c as described above, and the dopant concentration C_{D2} of the second region 140b may be equal to or greater than each of the dopant concentration C_{D1} of the first region 140a and the dopant concentration C_{D3} of the third region 140c. For example, in some example embodiments, the nitride layer 140 may have a highest dopant concentration C_{D2} in the second region 140b.

According to some example embodiments of the present disclosure, the nitride layer 140 may include a region having the same dopant concentration as or higher dopant concentration than other regions. However, the nitride layer 140 may not have a gradient where the dopant concentration increases as it approaches the gate electrode 120 as described above. For example, the dopant concentration C_{D1} of the first region 140a close to the gate electrode 120 may be lower than the dopant concentration C_{D2} of the second region 140b. The nitride layer 140, where the dopant concentration is high in a specific region, may be manufactured by discontinuously doping the dopant while depositing silicon nitride through, for example, an atomic layer deposition (ALD) process.

The nitride layer 140 according to some example embodiments of the present disclosure may contain the dopant in an amount of approximately 25 at % or less, approximately 24 at % or less, approximately 23 at % or less, approximately 22 at % or less, approximately 21 at % or less, approximately 20 at % or less, approximately 19 at % or less, approximately 18 at % or less, approximately 17 at % or less, or approximately 16 at % or less or approximately 15 at % or less relative to the total number of elements. In one example, although not particularly limited, the nitride layer 140 may contain dopants in an amount of approximately 0.01 at % or more, approximately 0.05 at % or more, approximately 0.1 at % or more, approximately 0.2 at % or more, approximately 0.3 at % or more, approximately 0.4 at % or more, approximately 0.5 at % or more, approximately 0.6 at % or more, approximately 0.7 at % or more, approximately 0.8 at % or more, approximately 0.9 at % or more, approximately 1.0 at % or more, approximately 1.1 at % or more, approximately 1.2 at % or more, approximately 1.3 at % or more, approximately 1.4 at % or more, or approximately 1.5 at % or more relative to the total number of elements.

In another non-limiting example, the nitride layer 140 may contain the dopant in an amount greater than approximately 0.5 at %, approximately 0.6 at % or more, approximately 0.7 at % or more, approximately 0.8 at % or more, approximately 0.9 at % or more, approximately 1 at % or more, approximately 1.1 at % or more, approximately 1.2 at % or more, approximately 1.3 at % or more, approximately 1.4 at % or more, or approximately 1.5 at % or more relative to the total number of elements (e.g., total element content). The nitride layer 140 may contain a dopant within a range formed by selecting the upper and lower limits described above.

The mole number of nitrogen contained in the nitride layer 140 according to some example embodiments of the present disclosure may be greater than the mole number of silicon. Through this, in the nitride layer 140, a deep trap is formed due to a change in the bonding structure, the trap density can be increased, and the insulating characteristics can be improved to reduce electron leakage.

The nitride layer 140 according to some example embodiments of the present disclosure may have a ratio of the mole number of nitrogen to the mole number of silicon of greater than 1 to less than 4/3. Specifically, the silicon oxide included in the nitride layer 140 may have a ratio of the mole number of nitrogen to the mole number of silicon of greater than 1 to less than 4/3. Through this, in the nitride layer 140, a deep trap is formed due to a change in the bonding structure, the trap density can be increased, and the insulating characteristics can be improved to reduce electron leakage.

The nitride layer 140 according to some example embodiments of the present disclosure may be amorphous. In some example embodiments, the silicon nitride included in the nitride layer 140 may be amorphous. Through this, it is easier to control the physical properties and improve the current leakage problem due to grain boundaries, which can help improve the performance and maintain reliability of the memory device 100a.

The thickness of the nitride layer 140 according to some example embodiments of the present disclosure may be approximately 1 nm to approximately 10 nm. The thickness of the nitride layer 140 may be, for example, approximately 1.5 nm or more, approximately 2 nm or more, approximately 2.5 nm or more, approximately 3 nm or more, approximately 3.5 nm or more, or approximately 4 nm or more, or approximately 9.5 nm or less, approximately 9 nm or less, approximately 8.5 nm or less, approximately 8 nm or less, approximately 7.5 nm or less, or approximately 7 nm or less. Through this, the memory device 100a having an optimized operating speed while having appropriate memory performance can be secured.

The gate insulating layer 130 according to some example embodiments of the present disclosure may be disposed between the gate electrode 120 and the nitride layer 140. In one example, the gate insulating layer 130 may contain oxide. In one example, the gate insulating layer 130 may include, but is not limited to, one or more of silicon oxide, silicon-germanium oxide, germanium oxide, lanthanum oxide, lanthanum aluminum oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate.

In some example embodiments, the gate insulating layer 130 may include ferroelectrics (e.g., ferroelectric material). In one example, the ferroelectrics may have spontaneous polarization characteristics due to the application an electric field, and may have remnant polarization even in a state in which there is no electric field after having the spontaneous polarization characteristics. In some example embodiments, the ferroelectrics may include oxide that contains one or more selected from among hafnium (Hf) and/or zirconium (Zr) and has ferroelectric properties. In some example embodiments, the ferroelectrics may include one or more selected from among hafnium oxide, hafnium silicon oxide, and/or hafnium aluminum oxide, which are oxides containing hafnium (Hf). The ferroelectrics may include one or more selected from among zirconium oxide and/or zirconium silicon oxide, which are oxides containing zirconium (Zr). The ferroelectrics may include hafnium-zirconium oxide (HZO), which is an oxide containing hafnium (Hf) and zirconium (Zr). In some example embodiments, the ferroelectrics are not limited to the oxides described above and may include one or more selected from among BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, LiTaO₃, KNaNbO₃, BaSrTiO₃, HF0·5Zr0·5O₂, PbZrₓTi₁₋ₓO₃ (0<x<1), Ba(Sr, Ti)O₃, Bi₄−xLaₓTi₃O₁₂ (0<x<1), SrBi₂Ta₂O₉, Pb₅Ge₅O₁₁, SrBi₂Nb₂O₉ and/or YMnO₃. In some example embodiments, the ferroelectric may include a compound doped with impurities, and the impurities may include one or more selected from a group consisting of carbon (C), silicon (Si), magnesium (Mg), aluminum (Al), yttrium (Y), nitrogen (N), germanium (Ge), and tin (Sn), gadolinium (Gd), lanthanum (La), scandium (Sc), and/or strontium (Sr).

In some example embodiments, the channel insulating layer 150 may be disposed between the channel layer 160 and the nitride layer 140. In some example embodiments, the channel insulating layer 150 may contain an insulating material. The gate insulating layer 130 may contain, for example, an oxide. Although not particularly limited, the gate insulating layer 130 and the channel insulating layer 150 may contain the same oxide. That is, the gate insulating layer 130 may contain the same oxide as the oxide contained in the channel insulating layer 150.

The memory device 100a according to some example embodiments of the present disclosure may further include a source electrode 200 and a drain electrode 300 electrically connected to the channel layer 160. In one example, at least a portion of the source electrode 200 and the drain electrode 300 may be disposed on the channel layer 160 or may be disposed within the substrate 101.

Referring to FIG. 1, the source electrode 200 and the drain electrode 300 may be spaced apart from each other in the second direction D2. In one example, the source electrode 200 and the drain electrode 300 may each contain one or more independently doped materials selected from among polysilicon, metal, conductive metal nitride, conductive metal silicide, and/or conductive metal oxide. In one example, the metal may include one or more selected from among aluminum (Al), copper (Cu), titanium (Ti), tantalum (Ta), rubidium (Ru), tungsten (W), molybdenum (Mo), platinum (Pt), nickel (Ni), and/or cobalt (Co). In one example, the conductive metal nitride may include one or more selected from TiAl and/or TiAlN. In some example embodiments, the conductive metal silicide may include one or more selected from among TiSi, TiSiN, TaSi, TaSiN, RuTiN, NiSi, and/or CoSi. In one example, the conductive metal oxide may include one or more selected from IrOx and/or RuOx.

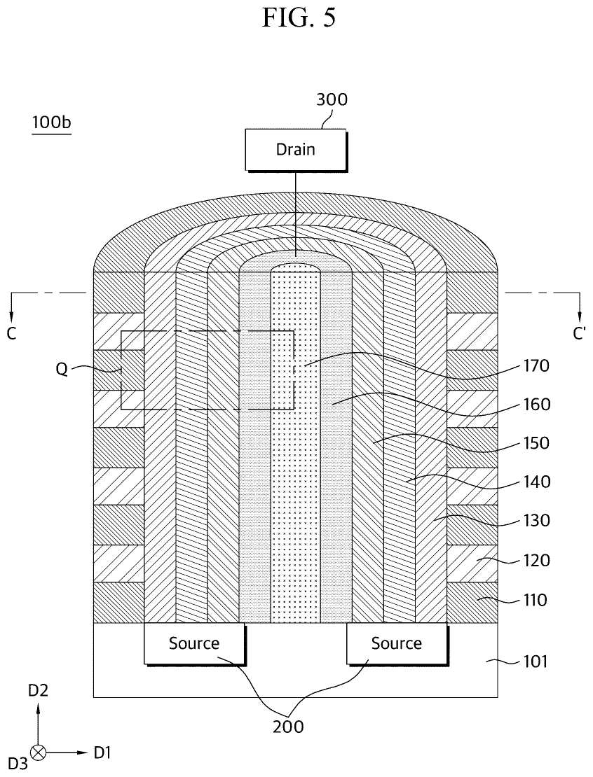

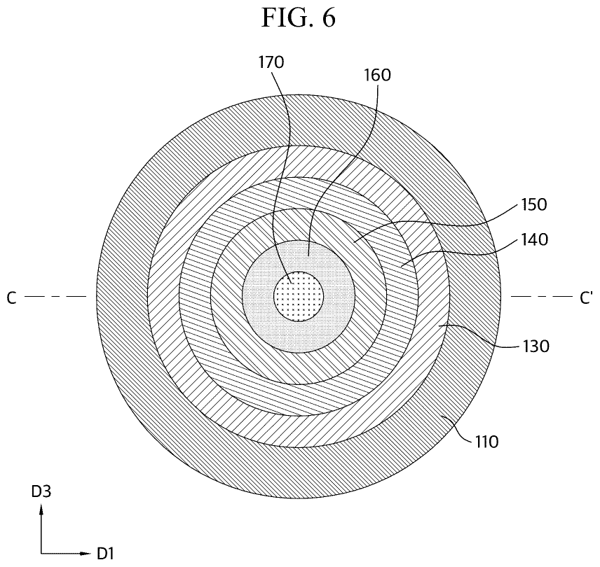

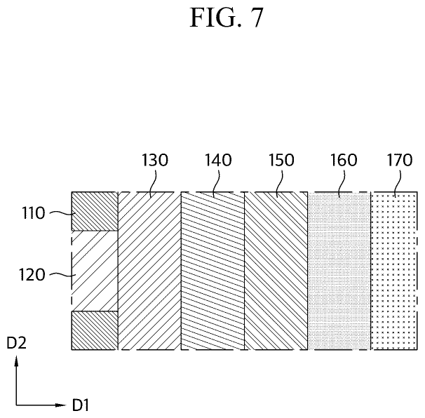

FIG. 5 is a simplified view of at least a portion of the memory device 100b according to some example embodiments of the present disclosure. FIG. 6 illustrates a cross-section cut along CC′ of FIG. 5. FIG. 7 is an enlarged view of portion Q of FIG. 5.

The memory device 100b according to some example embodiments of the present disclosure may include a filling layer 170 surrounded by the channel layer 160. In one example, the filling layer 170 may contain an insulating material, and the insulating material contained in the filling layer 170 may include, for example, one or more selected from a group consisting of air, silicon oxide, silicon nitride, and/or silicon oxynitride.

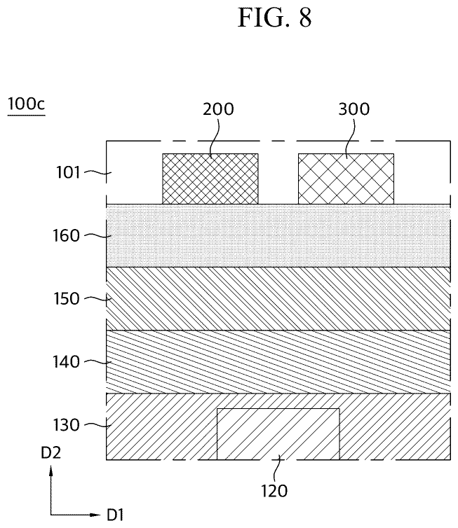

FIG. 8 is a simplified view of at least a portion of the memory device 100c according to some example embodiments of the present disclosure. In the memory device 100c illustrated in FIG. 8, unlike the memory devices 100a and 100b illustrated in FIGS. 1 to 7, the channel layer 160 and the substrate 101 may be disposed side by side. Referring to FIG. 8, the thickness direction of the nitride layer 140 may mean the second direction D2 in some example embodiments. Hereinafter, the content of FIG. 8 may refer to the description of FIGS. 1 to 7 unless there is a contradiction.

The gate electrode 120 according to some example embodiments of the present disclosure may be disposed between the substrate 101 and the channel layer 160 as described above.

Referring to FIG. 8, in one example, the gate electrode 120 may be disposed parallel to at least a portion of the channel layer 160. In one example, the channel layer 160 may be disposed parallel to the substrate 101. In one example, the channel layer 160 may be disposed parallel to the substrate 101 along the first direction D1.

Referring to FIG. 8, a memory device 100 according to some example embodiments of the present disclosure may include the source electrode 200 and the drain electrode 300. In one example, the source electrode 200 and the drain electrode 300 may be spaced apart from each other in the first direction D1. In one example, the source electrode 200 and the drain electrode 300 may be disposed on the channel layer 160 or disposed within the substrate 101. For example, in some example embodiments the source electrode 200 and the drain electrode 300 may be disposed on a surface of the channel layer 160 in the D2 direction. In some example embodiments, the channel layer 160 may be between the source electrode 200 and the drain electrode 300 in the second direction D2.

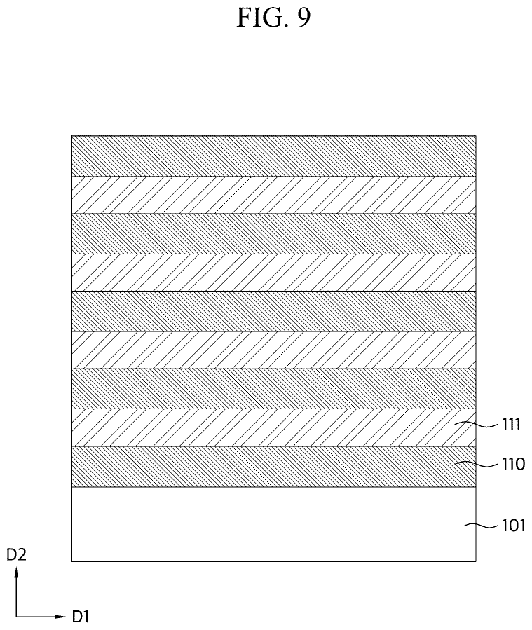

FIGS. 9 to 16 are diagrams for describing a method for manufacturing a memory device 100 according to an embodiment of the present disclosure. Hereinafter, as long as the description of the method for manufacturing the memory device 100 does not contradict, reference may be made to the above descriptions described with reference to FIGS. 1 to 7. Hereinafter, the method for manufacturing the memory device 100 in which the channel layer 160 is formed to extend along the second direction D2 intersecting with the first direction D1 parallel to the surface of the substrate 101, but this is only for convenience of description and is not limited thereto.

Referring to FIG. 9, in one example, a manufacturing method of the memory device 100 may include forming a mold structure by alternating a sacrificial layer 111 and a gap insulating layer 110 on a substrate 101. In one example, the sacrificial layer 111 closest to the substrate 101 may be closer to the substrate 101 than the gap insulating layer 110 closest to the substrate 101. In one example, the gap insulating layer 110 closest to the substrate 101 may be closer to the substrate 101 than the sacrificial layer 111 closest to the substrate 101. For example, one of the gap insulating layers 110 may contact both the substrate 101 and a sacrificial layer 111. In one example, the mold structure of the sacrificial layer 111 and the gap insulating layer 110 may be formed through deposition. In the present specification, the deposition may be performed through various methods such as chemical vapor deposition (CVD), physical vapor deposition (PVD), and ALD. In one example, unless otherwise specified, the components of the memory device 100 may be formed, for example, through deposition, but are not limited thereto.

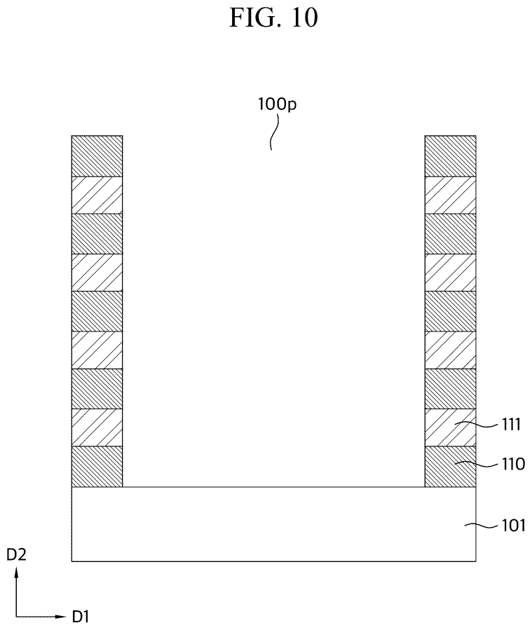

Referring to FIG. 10, in one example, the manufacturing method of the memory device 100 may include removing a portion of the mold structure of the sacrificial layer 111 and the gap insulating layer 110 to form a pillar-shaped hole 100p. One or two or more holes 100p may be present, and in the case where two or more holes are present, each hole 100p may be formed to be spaced apart from each other in the first direction D1. Although not shown in the drawing, when two or more holes 100p are present, the holes 100p may be formed to be spaced apart from each other in the first direction D1 and the third direction D3. The mold structure may be removed, for example, through an etching process.

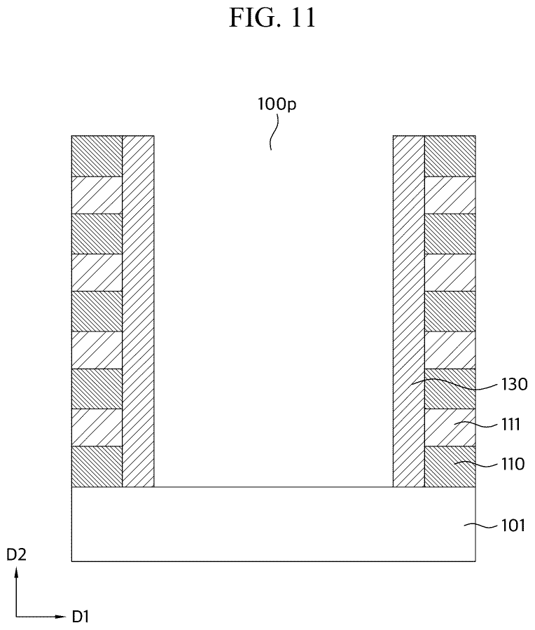

Referring to FIG. 11, in one example, the manufacturing method of the memory device 100 may include forming a gate insulating layer 130 on the gate electrode 120. In one example, the gate insulating layer 130 may be formed to overlap the sacrificial layer 111 in at least some regions of the gate insulating layer when viewed in the first direction D1. For example, in some example embodiments, the gate insulating layer 130 may overlap the sacrificial layer 111 and/or the gap insulating layer 110 in the first direction D1. In one example, the gate insulating layer 130 may be formed in the pillar-shaped hole 100p. In one example, the gate insulating layer 130 may be formed on the sacrificial layer 111 and also on the gap insulating layer 110. That is, in one example, the method for manufacturing the memory device 100 may include forming the gate insulating layer 130 in contact with at least a portion of each of the sacrificial layer 111 and the gap insulating layer 110.

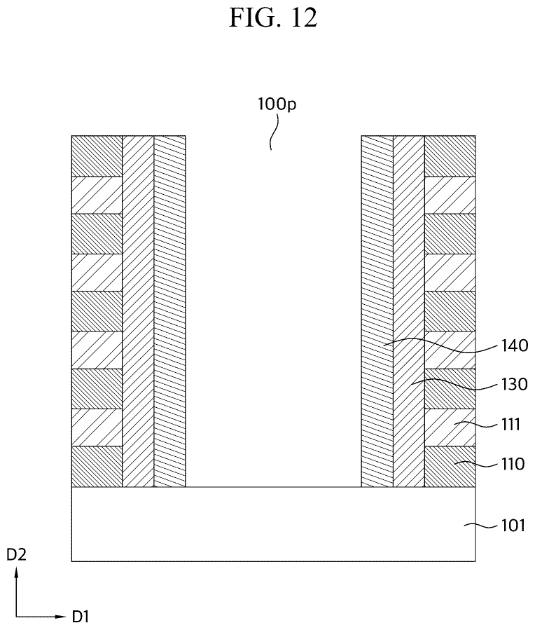

Referring to FIG. 12, in some example embodiments, the method for manufacturing the memory device 100 may include forming a nitride layer 140 containing nitride doped having a dopant on the gate insulating layer 130. Although not particularly limited, the nitride layer 140 may be formed by an atomic layer deposition (ALD) process as described above. In one example, the nitride layer 140 may be formed along a profile of the gate insulating layer 130. For example, in some example embodiments, the nitride layer 140 may be formed such that the nitride layer does not include a concentration gradient of dopant that increases toward the gate insulating layer 130. For example, some known methods of deposition may produce a concentration gradient of dopant across the nitride layer in which a concentration of the dopant is greatest where the doping is performed. In some example embodiments, by manufacturing the nitride layer 140 according to the disclosed methods, the nitride layer 140 may not have such a concentration gradient of the dopant.

In one example, the atomic layer deposition process for forming the nitride layer 140 may be performed by injecting a dopant precursor and a silicon (Si) precursor. In one example, the dopant precursor may vary depending on the type of dopant to be contained in the nitride layer 140, and is not particularly limited as long as it is used in the art.

For example, when the dopant is boron (B), its precursor may include one or more selected from B₂H₆ and B(CH₃)₃. When the dopant is aluminum (Al), its precursor may include Al(CH₃)₃. When the dopant is gallium (Ga), its precursor may include Ga(CH₃)₃. When the dopant is indium (In), its precursor may include In(CH₃)₃. When the dopant is thallium (Tl), its precursor may include Tl(OC₂H₅)₃.

For example, when the dopant is germanium (Ge), its precursor may include one or more selected from among GeH₄, GeHCl₃, GeH₂Cl₂, GeH₃Cl, GeCl₄, Ge₂H₆, Ge₂Cl₆, Ge(OCH₃)₄ and Ge[N(CH₃)₂]₄. When the dopant is tin (Sn), its precursor may include one or more selected from Sn(CH₃)₄ and SnCl₄. When the dopant is lead (Pb), its precursor may include one or more selected from lead (II) bis(2,2,6,6-tetramethyl-3,5-heptanedione, Pb(thd)₂) and PbCl₂.

For example, when the dopant is phosphorus (P), its precursor may include one or more selected from PH₃ and P(CH₃)₃. When the dopant is arsenic (As), its precursor may include one or more selected from AsH₃ and As(CH₃)₃. When the dopant is antimony (Sb), its precursor may include one or more selected from SbCl₃ and Sb(CH₃)₃. When the dopant is bismuth (Bi), its precursor may include one or more selected from BiCl₃ and/or Bi(CH₃)₃.

When the dopant includes a plurality of elements, doping may be performed by including precursors corresponding to the plurality of elements.

In one example, the silicon precursor may include, but is not limited to, one or more selected from among SiH₄, SiHCl₃, Si₂H₂Cl₂, SiCl₄, Si₂H₆, Si₂Cl₆, Si₂H₄Cl₂, Si₃H₃Cl₃, and Si₂H₂Cl₄ and/or Si(CH₃)₄.

In some example embodiments, the atomic layer deposition process for forming the nitride layer 140 may include a first deposition process performed by injecting a silicon (Si) precursor and a second deposition process performed by injecting a dopant precursor.

In some example embodiments, the atomic layer deposition process for forming the nitride layer 140 may be performed so that the first deposition process and the second deposition process overlap at least in part. For example, the first deposition process and the second deposition process may be performed to start simultaneously and may be performed to end simultaneously. Through this, the dopant concentration of the nitride layer 140 may be uniform throughout the nitride layer 140.

In some example embodiments, the atomic layer deposition process for forming the nitride layer 140 may be performed discontinuously while the first deposition process is continuously performed. Further, in the atomic layer deposition process for forming the nitride layer 140, after performing the first deposition process, the first deposition process may be performed discontinuously while the second deposition process is continuously performed. Through this, the nitride layer 140 may be manufactured so that the dopant concentration is high in a specific region.

In one example, the atomic layer deposition process for forming the nitride layer 140 may include a third deposition process performed by further injecting a nitrogen precursor. The nitrogen precursor is not particularly limited as long as it is used in the art, but may include, for example, one or more selected from among ammonia (NH₃), plasma N₂, plasma NH₃, N₂H₄, and an azide (N₃-) compound. The first deposition process and the third deposition process may be performed to start simultaneously and may be performed to end simultaneously.

In one example, an injection amount of each precursor injected in the first deposition process, the second deposition process, and the third deposition process described above may vary depending on the design of a thickness or doping degree of the nitride layer 140.

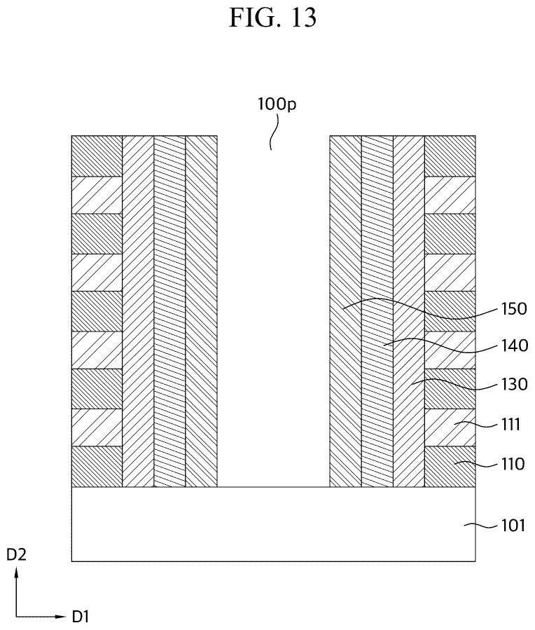

Referring to FIG. 13, in one example, the method for manufacturing the memory device 100 may include forming a channel insulating layer 150 on the nitride layer 140. In one example, the channel insulating layer 150 may be formed along a profile of the nitride layer 140.

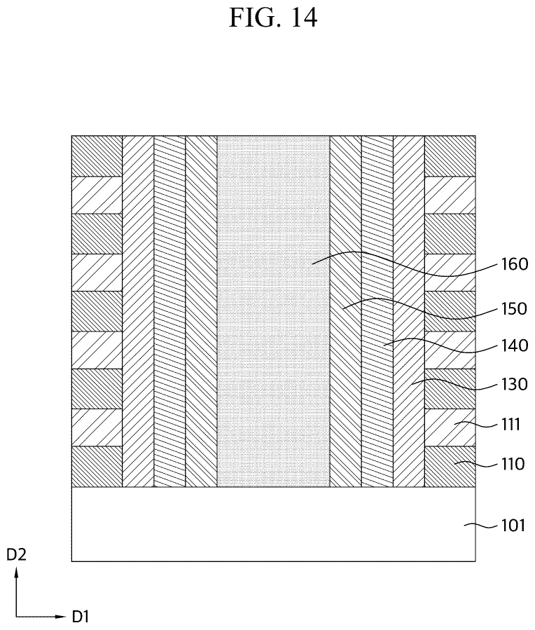

Referring to FIG. 14, in one example, the method for manufacturing the memory device 100 may include forming a channel layer 160 to extend along the second direction D2 within the hole 100p. In one example, the channel layer 160 may be formed along a profile of the channel insulating layer 150. In one example, the channel layer 160 may fill a portion or all of the remaining area of the hole 100p.

Although not illustrated in the drawing, in one example, the method for manufacturing the memory device 100 may include forming a filling layer 170 so as to extend along the second direction D2 within the hole 100p. In one example, the filling layer 170 may be formed along the profile of the channel layer 160. In one example, the filling layer 170 may fill the entire remaining area of the hole 100p.

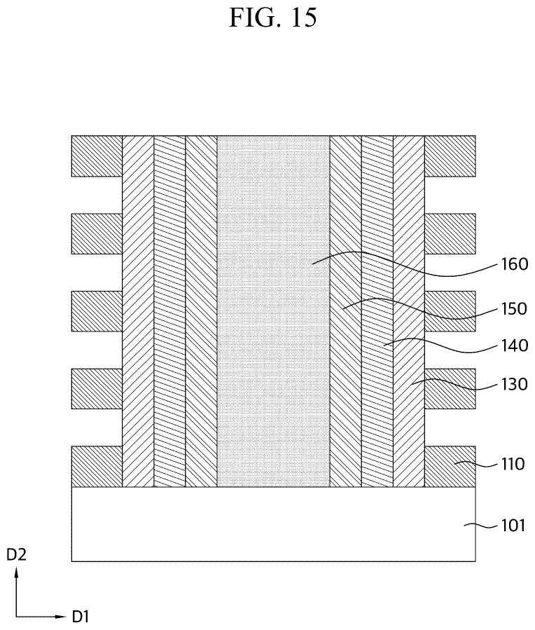

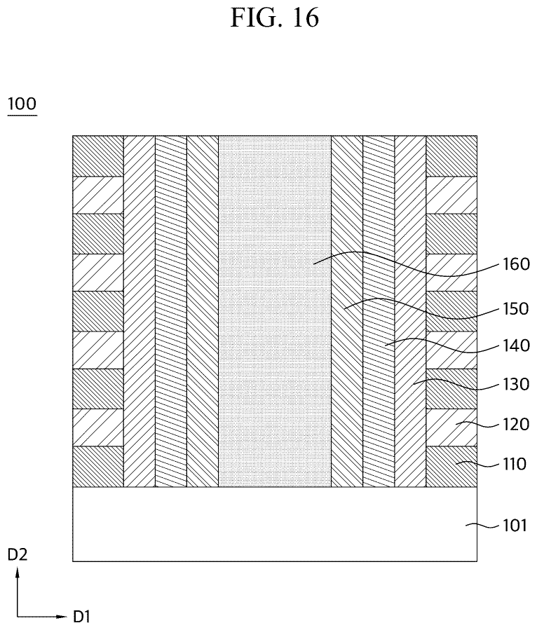

Referring to FIGS. 15 and 16, in one example, the method for manufacturing the memory device 100 may include removing the sacrificial layer 111 and forming the gate electrode 120 on at least a portion of the sacrificial layer 111 removed. The gate electrode 120 may be formed through a replacement process. That is, the gate electrode 120 may be formed by replacing the sacrificial layer 111. Through this, the memory device 100 according to one embodiment of the present inventive concepts may be manufactured.

Hereinafter, some example embodiments of the present application will be additionally described with reference to specific examples. The example embodiments and comparative examples are merely illustrative of the present application and do not limit the scope of the appended claims. It is obvious to those skilled in the art that various changes and modifications to the example embodiments are possible within the scope and technical idea of the present application. In addition, it is natural that such changes and modifications fall within the scope of the appended claims.

### Modeling

In modeling, first-principles molecular dynamics (AIMD) calculations were performed using the VASP code to generate an amorphous structure. In this case, a melt-quench method was adopted in which the temperature is gradually lowered while the material is in a molten state. First, the molten state was maintained at approximately 3000K for approximately 30 ps to generate a starting structure, and then approximately 25 structures were sampled at approximately 1 ps intervals from approximately 6 ps to approximately 30 ps. After that, the melting was performed at a higher temperature of approximately 5000K for approximately 1 ps and at approximately 3000K for approximately 10 ps, and then quenching was performed from approximately 3000K to approximately 0K for approximately 60 ps to generate the final structure. This process was performed for a total of approximately 4 sets, and a total of approximately 100 structures were sampled for each composition ratio. For the sampled structure, the electron density in a ground state was calculated, and then the results calculated on a plane-wave basis were post-processed and calculated on an atomic orbital basis using LOBSTER. Then, the strength of the chemical bond (ICOBI) between atoms was calculated. It was assumed that there was a chemical bond when the ICOBI value was approximately 0.30 or higher.

### Experimental Example 1

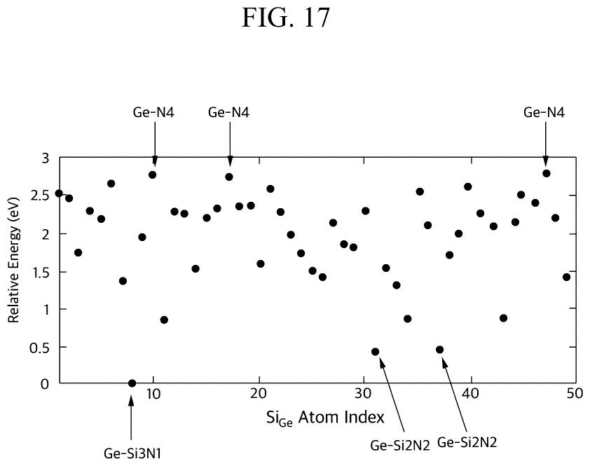

Through the modeling, the characteristics of the charge trap of the nitride layer 140 containing a silicon nitride having a dopant were analyzed, and the results are illustrated in FIG. 17. Here, the dopant is germanium (Ge).

FIG. 17 is a graph showing the relative energy (eV) after each germanium (Ge) element is substituted for the position of silicon in the existing amorphous silicon nitride and the structure is optimized. It can be confirmed that, compared to the case where the germanium (Ge) element is bonded with four nitrogens (N), the energy is relatively lower (i.e., more stable) when the germanium (Ge) element is bonded with one nitrogen (N) and three silicons (Si), or two nitrogens (N) and two silicons (Si). Through this, it can be expected that the Si—Si bonding network will be strengthened when germanium is doped compared to when germanium is not doped.

### Experimental Example 2

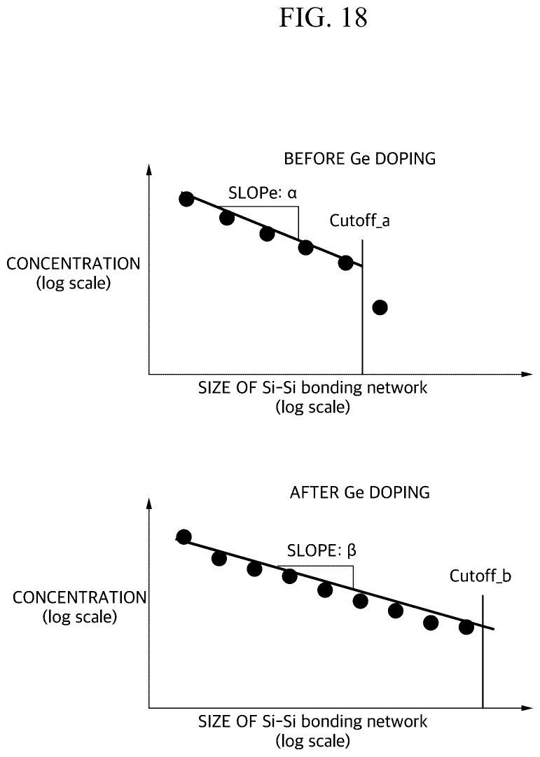

Through the modeling, the characteristics of charge trapping of the nitride layer 140 containing the silicon nitride having a dopant analyzed, and the results are illustrated in FIGS. 18 to 20. Here, the dopant is germanium (Ge).

FIG. 18 is a graph showing the frequency of occurrence by size of the silicon (Si)-silicon (Si) bonding network (i.e., the number of Si elements connected in a row) in a log scale. Referring to FIG. 18, as a result of sampling approximately 100 structures each before and after the germanium element (Ge) was doped into silicon nitride, it was found that a slope (α) of a graph before being doped with germanium (Ge) was greater than the slope (β) of the graph after being doped with germanium (Ge) (α>β). In addition, through the larger cutoff value (a<b) in FIG. 18, it can be confirmed that the probability of existence of a longer Si—Si bond and a larger Si—Si bonding network increases after germanium (Ge) doping. When the larger Si—Si bonding network is generated, a deep trap can be generated, and as a result, trapping occurs more easily as the capture cross-section of electrons increases as the electrons pass by the electric field.

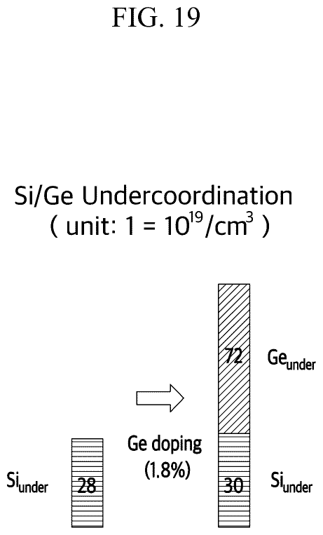

FIG. 19 is a graph showing the number of coordination defects in the nitride layer 140 according to the coordination of the germanium element, for a nitride layer 140 doped with germanium (Ge) at approximately 1.8 at % relative to the total elements. Referring to FIG. 19, it can be confirmed that there are more undercoordinated elements when the nitride layer 140 is doped with germanium compared to when the nitride layer 140 is not doped with germanium. These coordination defects induce reorganization of chemical bonds, allowing the entire nitride layer 140 to trap electric charges more easily.

### Experimental Example 3

Through the modeling, when two electrons or two holes were injected into the nitride layer 140 containing the silicon nitride having a dopant, the amount of change in the number of electric charges of each element was measured. Here, the dopant is germanium (Ge).

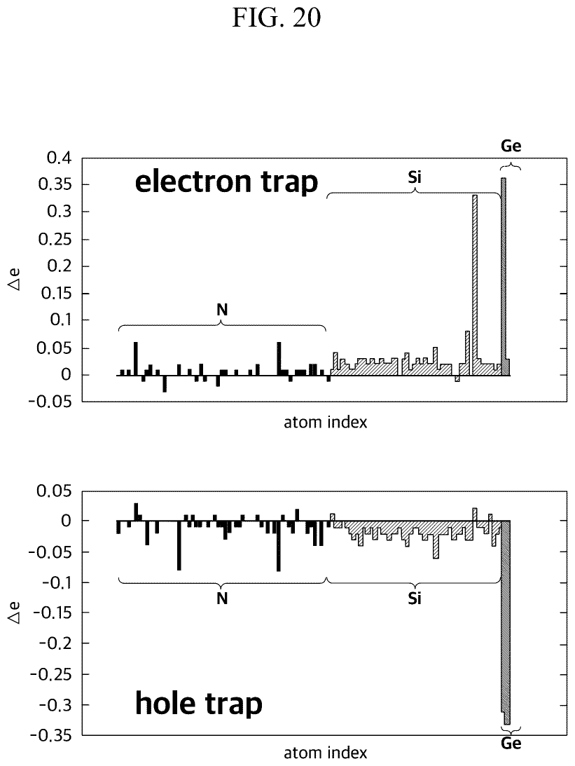

FIG. 20 is a graph showing the amount of change in electric charge of each element when electrons and holes are trapped. Referring to FIG. 20, it can be confirmed that the amount of change in electric charge of the germanium element changes significantly not only when electrons are trapped, but also when holes are trapped. That is, not only electron trapping but also hole trapping may be possible through germanium (Ge) doping.

### Experimental Example 4

This is a graph showing the relative effect of the dopant on charge traps (charge trap participation rate) in a nitride layer 140 containing silicon nitride having a dopant through the above modeling. The influence of the dopant on charge traps (i.e., charge trap participation rate) was shown as a bar graph by analyzing the change in Löwdin charge for the dopant before and after the charge trap.

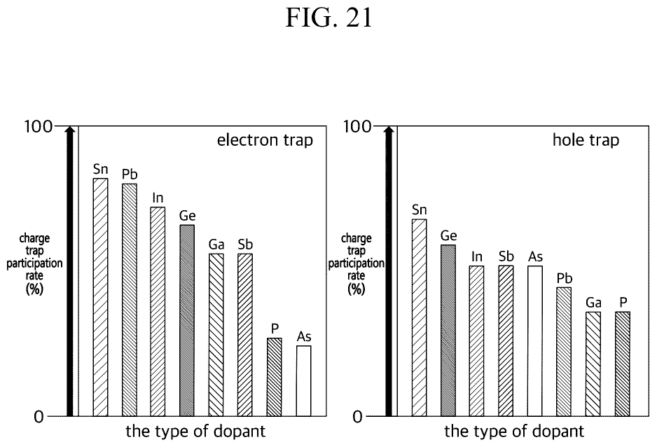

FIG. 21 is a graph showing the change in Löwdin charge (i.e., charge trap participation rate, %) for each dopant when electrons and holes are trapped for a nitride layer (140) having approximately 1.8 at % relative to the total elements of the dopant. Referring to FIG. 21, in all the sampled amorphous structures, when the dopant atoms participate in the trap, the charge trap participation rate is 100%, and in all the amorphous structures, when the dopant atoms do not participate in the trap, the charge trap participation rate is 0%. The closer the charge trap participation rate is to 100%, the greater the change in Löwdin charge, and the greater the influence of the dopant on the charge trap.

Referring to FIG. 21, when gallium (Ga), indium (In), germanium (Ge), tin (Sn), lead (Pb), phosphorus (P), arsenic (As), and antimony (Sb) are used as dopants, it suggests that they contribute to charge traps. That is, the additional charge is spatially localized to a small number of elements including the dopant. Additionally, the high charge trap participation rate of the dopant can be seen as the dopant creating a deep trap. In the case of phosphorus (P), arsenic (As), lead (Pb), and gallium (Ga), which have relatively low contributions, the contribution can be increased by increasing the dopant concentration.

The present disclosure can provide a memory device having improved charge trap flash (CTF) characteristics, a wide memory window, and improved retention rate.

The effects of the present disclosure are not limited to the effects mentioned above, and other effects not mentioned can be clearly understood by those skilled in the art from the description below.

The present disclosure is not limited to the embodiments described above, but can be manufactured in various different forms, and a person having ordinary knowledge in the technical field to which the present disclosure belongs will understand that the present disclosure may be implemented in other specific forms without changing the technical idea or essential features of the present disclosure. Therefore, it should be understood that the embodiments described above are exemplary in all respects and not limiting.

What is claimed is:

1. A memory device comprising:
a substrate;
a channel layer on a surface of the substrate;
a gate electrode on the channel layer;
a nitride layer between the channel layer and the gate electrode, the nitride layer containing silicon nitride having a dopant;
a gate insulating layer between the gate electrode and the nitride layer; and
a channel insulating layer between the channel layer and the nitride layer,
wherein the nitride layer includes a first region adjacent to the gate electrode in a thickness direction of the nitride layer and a second region further from the gate electrode than the first region in the thickness direction of the nitride layer,
the dopant includes one or more of boron (B), aluminum (Al), gallium (Ga), indium (In), thallium (Tl), germanium (Ge), tin (Sn), lead (Pb), phosphorus (P), arsenic (As), antimony (Sb), or bismuth (Bi), and
a ratio C_{D1}/C_{D2} of a dopant concentration C_{D1} of the first region and a dopant concentration C_{D2} of the second region is in a range of 0.8 to 1.2.

2. The memory device of claim 1, wherein
the nitride layer further includes a third region between the first region and the second region,
a ratio C_{D3}/C_{D1} of a dopant concentration C_{D3} of the third region and the dopant concentration C_{D1} of the first region is in a range of 0.8 to 1.2, and
a ratio C_{D3}/C_{D2} of the dopant concentration C_{D3} of the third region and the dopant concentration C_{D2} of the second region is in a range of 0.8 to 1.2.

3. The memory device of claim 1, wherein the nitride layer contains the dopant in an amount of 25 at % or less relative to a total element content of the nitride layer.

4. The memory device of claim 1, wherein a number of moles of nitrogen contained in the nitride layer is greater than a number of moles of silicon.

5. The memory device of claim 1, wherein the silicon nitride has a ratio of a mole number of nitrogen to a mole number of silicon of greater than 1 and less than 4/3.

6. The memory device of claim 1, wherein the nitride layer is amorphous.

7. The memory device of claim 1, wherein a thickness of the nitride layer is in a range of 1 nm to 10 nm.

8. The memory device of claim 1, wherein the gate insulating layer contains an oxide.

9. The memory device of claim 1, wherein the gate insulating layer contains ferroelectric material.

10. The memory device of claim 1, wherein
the channel layer extends along a first direction intersecting with a second direction, the second direction parallel to the surface of the substrate, and
the gate electrode surrounds at least a portion of the channel layer.

11. The memory device of claim 10, further comprising:
a source electrode and a drain electrode each electrically connected to the channel layer,
wherein the source electrode and the drain electrode are spaced apart from each other in the first direction.

12. The memory device of claim 10, further comprising:
a gap insulating layer that overlaps the gate electrode in at least some regions in the first direction, the gap insulating layer surrounds at least a portion of the channel layer.

13. The memory device of claim 12, wherein
the gate electrode includes a plurality of gate electrodes,
the plurality of gate electrodes includes adjacent gate electrodes, the adjacent gate electrodes spaced apart from each other in the first direction, and
the gap insulating layer fills a space between the adjacent gate electrodes spaced apart from each other.

14. The memory device of claim 1, wherein the channel layer is parallel to the substrate.

15. The memory device of claim 14, further comprising:
a source electrode and a drain electrode each electrically connected to the channel layer,
wherein the source electrode and the drain electrode are spaced apart from each other in a first direction intersecting with a second direction, the first direction parallel to the surface of the substrate.

16. The memory device of claim 15, wherein
the channel insulating layer contains an oxide, and
the gate insulating layer contains a same oxide as the oxide included in the channel insulating layer.

17. A memory device comprising:
a substrate;
a channel layer on a surface of the substrate;
a gate electrode on the channel layer;
a nitride layer between the channel layer and the gate electrode, the nitride layer containing silicon nitride having a dopant;
a gate insulating layer between the gate electrode and the nitride layer; and
a channel insulating layer between the channel layer and the nitride layer,
wherein the nitride layer includes a first region adjacent to the gate electrode in a thickness direction of the nitride layer, a second region further from the gate electrode than the first region in the thickness direction of the nitride layer, and a third region between the first region and the second region,
the dopant includes one or more of boron (B), aluminum (Al), gallium (Ga), indium (In), thallium (Tl), germanium (Ge), tin (Sn), lead (Pb), phosphorus (P), arsenic (As), antimony (Sb), or bismuth (Bi), and
a dopant concentration C_{D2} of the second region is equal to or greater than each of a dopant concentration C_{D1} of the first region and a dopant concentration C_{D3} of the third region.

18. The memory device of claim 17, further comprising:
a filling layer surrounded by the channel layer.

19. The memory device of claim 18, wherein the filling layer contains one or more of air, silicon oxide, silicon nitride, or silicon oxynitride.

20. A memory device comprising:
a substrate;
a channel layer on a surface of the substrate;
a gate electrode on the channel layer;
a nitride layer between the channel layer and the gate electrode, the nitride layer containing silicon nitride having a dopant;
a gate insulating layer between the gate electrode and the nitride layer; and
a channel insulating layer between the channel layer and the nitride layer,
wherein the nitride layer includes a first region adjacent to the gate electrode in a thickness direction of the nitride layer, a second region further from the gate electrode than the first region in the thickness direction of the nitride layer, and a third region between the first region and the second region,
the dopant includes one or more of boron (B), aluminum (Al), gallium (Ga), indium (In), thallium (Tl), germanium (Ge), tin (Sn), lead (Pb), phosphorus (P), arsenic (As), antimony (Sb), or bismuth (Bi), and
a ratio C_{D1}/C_{D2} of a dopant concentration C_{D1} of the first region and a dopant concentration C_{D2} of the second region in a range of 0.8 to 1.2,
a ratio C_{D3}/C_{D1} of a dopant concentration C_{D3} of the third region and the dopant concentration C_{D1} of the first region is in a range of 0.8 to 1.2,
a ratio C_{D3}/C_{D2} of the dopant concentration C_{D3} of the third region and the dopant concentration C_{D2} of the second region is in a range of 0.8 to 1.2,
the nitride layer contains doped germanium in an amount of 25 at % or less relative to a total element content of the nitride layer,
a mole number of nitrogen contained in the nitride layer is greater than a mole number of silicon, and
a thickness of the nitride layer is in a range of 1 nm to 10 nm.
